(19) United States
(12) Patent Application Publication
(10) Pub. No.: US 2022/0077183 A1
(43) Pub. Date: Mar. 10, 2022

(54) SEMICONDUCTOR DEVICE AND METHOD OF MANUFACTURING SAME

(71) Applicant: Kioxia Corporation, Tokyo (JP)

(72) Inventors: Takaumi MORITA, Kuwana (JP); Hisashi OKUCHI, Yokkaichi (JP); Keiichi SAWA, Yokkaichi (JP); Hiroyuki YAMASHITA, Yokkaichi (JP); Toshiaki YANASE, Yokohama (JP); Tsubasa IMAMURA, Kuwana (JP)

(73) Assignee: Kioxia Corporation, Tokyo (JP)

(21) Appl. No.: 17/197,305

(22) Filed: Mar. 10, 2021

(30) Foreign Application Priority Data
Sep. 10, 2020 (JP) 2020-152316

(51) Int. Cl. H01L 27/11582; H01L 27/11556; H01L 27/11519; H01L 27/11565

(52) U.S. Cl. CPC H01L 27/11582; H01L 27/11565; H01L 27/11519; H01L 27/11556

(57) ABSTRACT

In one embodiment, a semiconductor device includes a substrate, and a plurality of electrode layers provided separately from each other in a first direction perpendicular to a surface of the substrate. The device further includes a first insulator, a charge storage layer, a second insulator, a first semiconductor region including silicon, and a second semiconductor region including silicon and carbon, which are provided in order on side faces of the electrode layers, wherein an interface between the first semiconductor region and the second insulator includes fluorine.

### CROSS REFERENCE TO RELATED APPLICATION

This application is based upon and claims the benefit of priority from the prior Japanese Patent Application No. 2020-152316, filed on Sep. 10, 2020, the entire contents of which are incorporated herein by reference.

### FIELD

Embodiments described herein relate to a semiconductor device and a method of manufacturing the same.

### BACKGROUND

In a semiconductor memory such as a three-dimensional memory, it is desirable to improve performance of a channel semiconductor layer.

### BRIEF DESCRIPTION OF THE DRAWINGS

FIG. 1 is a sectional view illustrating a structure of a semiconductor device of a first embodiment;

FIGS. 2 to 9 are sectional views illustrating a method of manufacturing the semiconductor device of the first embodiment;

FIG. 10 is a sectional view illustrating a structure of a semiconductor device of a second embodiment;

FIG. 11 is an enlarged sectional view illustrating the structure of the semiconductor device of the second embodiment;

FIG. 12 is another enlarged sectional view illustrating the structure of the semiconductor device of the second embodiment;

FIGS. 13 to 26 are sectional views illustrating a method of manufacturing the semiconductor device of the second embodiment;

FIG. 27 is a sectional view illustrating a structure of a semiconductor device of a third embodiment;

FIG. 28 is another sectional view illustrating the structure of the semiconductor device of the third embodiment;

FIGS. 29 and 30 are sectional views illustrating a method of manufacturing a semiconductor device of a fourth embodiment;

FIGS. 31A and 31B are sectional views for comparing the method of manufacturing the semiconductor device of the first embodiment and the method of manufacturing the semiconductor device of the fourth embodiment;

FIG. 32 is a table for describing a fluorine additive of the fourth embodiment;

FIGS. 33A to 33C are structural formulas for describing a partial structure of the fluorine additive of the fourth embodiment; and

FIGS. 34 to 36 are sectional views illustrating a method of manufacturing a semiconductor device of a fifth embodiment.

### DETAILED DESCRIPTION

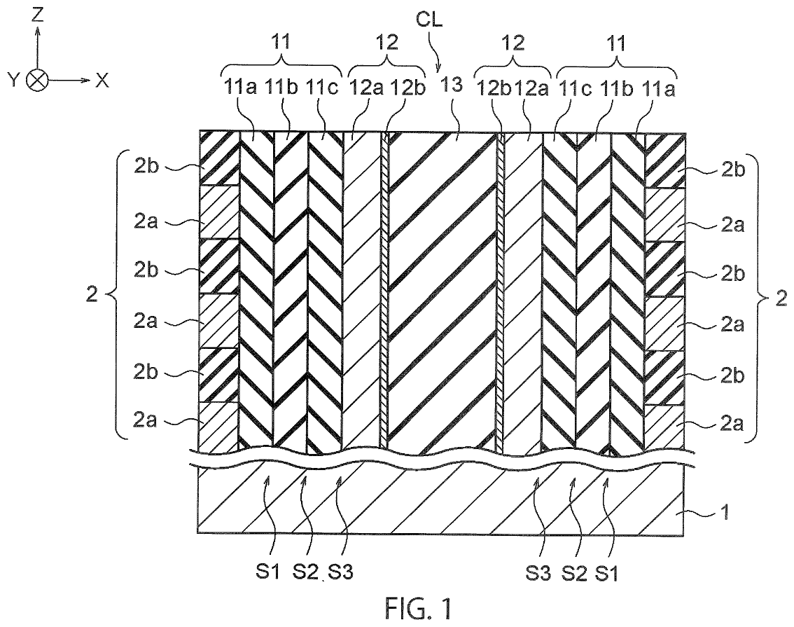

Embodiments will now be explained with reference to the accompanying drawings. From FIGS. 1 to 36, same signs are attached to same configurations and redundant description will be omitted.

In one embodiment, a semiconductor device includes a substrate, and a plurality of electrode layers provided separately from each other in a first direction perpendicular to a surface of the substrate. The device further includes a first insulator, a charge storage layer, a second insulator, a first semiconductor region including silicon, and a second semiconductor region including silicon and carbon, which are provided in order on side faces of the electrode layers, wherein an interface between the first semiconductor region and the second insulator includes fluorine.

### First Embodiment

FIG. 1 is a sectional view illustrating a structure of a semiconductor device of the first embodiment. The semiconductor device in FIG. 1 is a three-dimensional memory for example.

The semiconductor device in FIG. 1 includes a substrate 1, a stacked film 2, a memory insulator 11, a channel semiconductor layer 12, and a core insulator 13. The stacked film 2 includes a plurality of electrode layers 2a and a plurality of insulating layers 2b. The memory insulator 11 includes a block insulator 11a, a charge storage layer 11b, and a tunnel insulator 11c. The block insulator 11a is an example of a first insulator, and the tunnel insulator 11c is an example of a second insulator. The channel semiconductor layer 12 includes a semiconductor region 12a and a semiconductor region 12b. The semiconductor region 12a is an example of a first semiconductor region, and the semiconductor region 12b is an example of a second semiconductor region.

The substrate 1 is a semiconductor substrate such as an Si (silicon) substrate, for example. FIG. 1 illustrates an X direction and a Y direction parallel to a surface of the substrate 1 and perpendicular to each other, and a Z direction perpendicular to the surface of the substrate 1. In the present description, a +Z direction is handled as an upper direction, and a −Z direction is handled as a lower direction. The −Z direction may coincide with a gravity direction or may not coincide with the gravity direction. The Z direction is an example of a first direction.

The stacked film 2 includes the plurality of electrode layers 2a and the plurality of insulating layers 2b alternately stacked above the substrate 1. The electrode layers 2a are separated from each other in the Z direction by being stacked alternately with the insulating layers 2b. The electrode layers 2a are used as word lines or selection lines for the three-dimensional memory. The electrode layers 2a each include a metal layer such as a W (tungsten) layer, for example. The insulating layers 2b each are an SiO₂ film (silicon oxide film), for example.

The semiconductor device in FIG. 1 further includes a plurality of columnar portions CLs formed in the stacked film 2 above the substrate 1 and having a columnar shape extending in the Z direction. FIG. 1 illustrates one of the columnar portions CLs. A shape of each columnar portion CL is columnar for example. Each columnar portion CL includes the memory insulator 11, the channel semiconductor layer 12 and the core insulator 13 formed in order in the stacked film 2, and configures a plurality of cell transistors (memory cells) and a plurality of selection transistors.

The block insulator 11a is formed on a side face of the stacked film 2, that is, the side faces of the electrode layers 2a and the insulating layers 2b. The block insulator 11a is the SiO₂ film for example.

The charge storage layer 11b is formed on the side face of the block insulator 11a. The charge storage layer 11b is an insulator such as an SiN film (silicon nitride film) for example, and may be a semiconductor layer such as a polysilicon layer. The charge storage layer 11b is capable of storing signal charges for the three-dimensional memory for each memory cell. FIG. 1 illustrates an interface S1 of the block insulator 11a and the charge storage layer 11b.

The tunnel insulator 11c is formed on the side face of the charge storage layer 11b. The tunnel insulator 11c is an SiON film (silicon oxynitride film) for example. FIG. 1 illustrates an interface S2 of the charge storage layer 11b and the tunnel insulator 11c.

The semiconductor region 12a is formed on the side face of the tunnel insulator 11c. A thickness of the semiconductor region 12a is equal to or smaller than 10 nm for example, and is equal to or smaller than 3 nm here. The semiconductor region 12a is the polysilicon layer for example. FIG. 1 illustrates an interface S3 of the tunnel insulator 11c and the semiconductor region 12a.

The semiconductor region 12b is formed on the side face of the semiconductor region 12a. The thickness of the semiconductor region 12b of the present embodiment is set thinner than the thickness of the semiconductor region 12a. The thickness of the semiconductor region 12b is equal to or smaller than 1 nm for example, and is about 0.1 nm here. The semiconductor region 12b is an SiC (silicon carbide) film for example, and Si (silicon) atoms and C (carbon) atoms in the semiconductor region 12b form an Si—C bond. A concentration of the C atoms in the semiconductor region 12b is equal to or lower than 1.0×10²² cm⁻³ for example. The concentration of the C atoms can be obtained using EDX or EELS. The semiconductor region 12b may be an SiC region which is so thin that it cannot be called the SiC film.

The core insulator 13 is formed on the side face of the semiconductor region 12b, and is positioned at a center of each columnar portion CL. The core insulator 13 is the SiO₂ film for example.

Next, further details of the semiconductor device in FIG. 1 will be described.

Each columnar portion CL of the present embodiment includes F (fluorine) atoms. For example, each columnar portion CL includes the F atoms in the semiconductor region 12a and the tunnel insulator 11c, and may further include the F atoms in the charge storage layer 11b and the block insulator 11a. In addition, the F atoms are included in the interface S3 of the semiconductor region 12a and the tunnel insulator 11c, and may be further included in the interface S2 of the tunnel insulator 11c and the charge storage layer 11b and the interface S1 of the charge storage layer 11b and the block insulator 11a. Further, the F atoms may be included in the semiconductor region 12b, in the interface between the semiconductor region 12b and the semiconductor region 12a, in the core insulator 13 and in the interface between the core insulator 13 and the semiconductor region 12b.

The present embodiment makes it possible to terminate defects and dangling bonds of the semiconductor region 12a, the tunnel insulator 11c and the interface S3 by the F atoms by including the F atoms in the semiconductor region 12a, the tunnel insulator 11c and the interface S3. This makes it possible to improve reliability of the semiconductor region 12a and the tunnel insulator 11c. The F atoms form an Si—F bond with the Si atoms in the semiconductor region 12a, the tunnel insulator 11c and the interface S3, for example. Generally, since many defects and dangling bonds that are terminating objects are present in the interface S3, it is desirable to include many F atoms in the interface S3. The concentration of the F atoms in the semiconductor region 12a, the tunnel insulator 11c and the interface S3 of the present embodiment is equal to or lower than 1.0×10²² cm⁻³ for example. The concentration of the F atoms can be obtained using the EDX or the EELS.

Such an effect can be obtained also in the other part in each columnar portion CL. For example, by including the F atoms in the interface S2 and the interface S1, it is possible to terminate the defects and the dangling bonds of the interface S2 and the interface S1 by the F atoms. The concentration of the F atoms in the charge storage layer 11b, the block insulator 11a, the interface S2 and the interface S1 of the present embodiment is equal to or lower than 1.0×10²² cm⁻³ for example. The F atoms form the Si—F bond with the Si atoms in the charge storage layer 11b, the block insulator 11a, the interface S2 and the interface S1, for example. In addition, the F atoms in the semiconductor region 12b and the both interfaces form the Si—F bond and a C—F bond with the Si atoms and the C atoms in the semiconductor region 12b and the both interfaces, for example. The concentration of the F atoms in the semiconductor region 12b and the both interfaces of the present embodiment is equal to or lower than 1.0×10²² cm⁻³ for example.

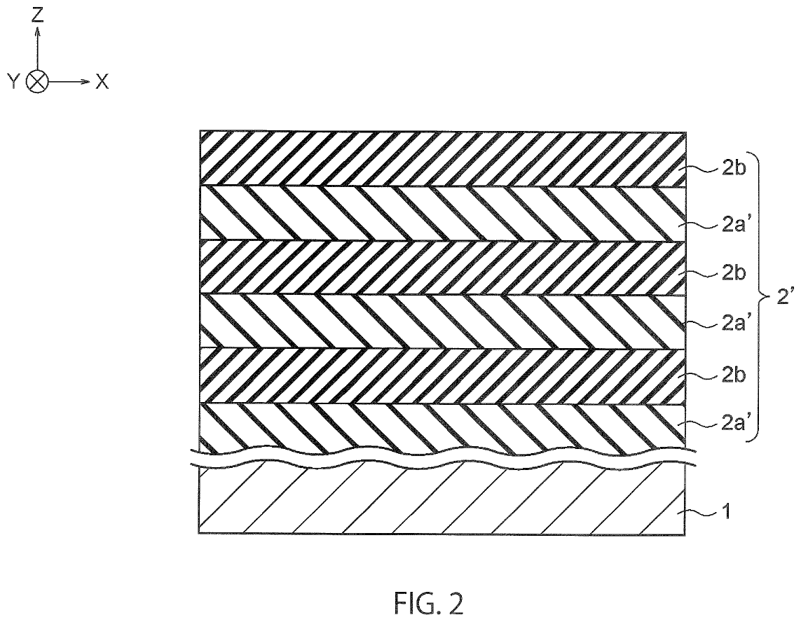

In the present embodiment, when the semiconductor region 12b is formed on the side face of the semiconductor region 12a, the F atoms are introduced into each columnar portion CL. The details of the processing will be described later with reference to FIGS. 2 to 9.

FIGS. 2 to 9 are sectional views illustrating a method of manufacturing the semiconductor device of the first embodiment. First, a stacked film 2′ alternately including a plurality of sacrificing layers 2a′ and the plurality of insulating layers 2b is formed above the substrate 1 (FIG. 2). As a result, the sacrificing layers 2a′ are formed so as to be separated from each other in the Z direction. The sacrificing layers 2a′ each are a silicon nitride film for example, and have the thickness of about 50 nm. The insulating layers 2b each are the silicon oxide film as described above for example, and have the thickness of about 50 nm. The sacrificing layers 2a′ are examples of first films.

The sacrificing layers 2a′ each are formed using SiH₂Cl₂ and NH₃ at 300-850° C. and in a decompression environment (2000 Pa or lower) by CVD (Chemical Vapor Deposition) (“H” denotes hydrogen, “Cl” denotes chlorine, and “N” denotes nitrogen). The insulating layers 2b each are formed using TEOS (tetraethyl orthosilicate) at 300-700° C. and in the decompression environment (2000 Pa or lower) by the CVD, for example. The stacked film 2 of the present embodiment is formed via another layer (an inter layer dielectric for example) above the substrate 1.

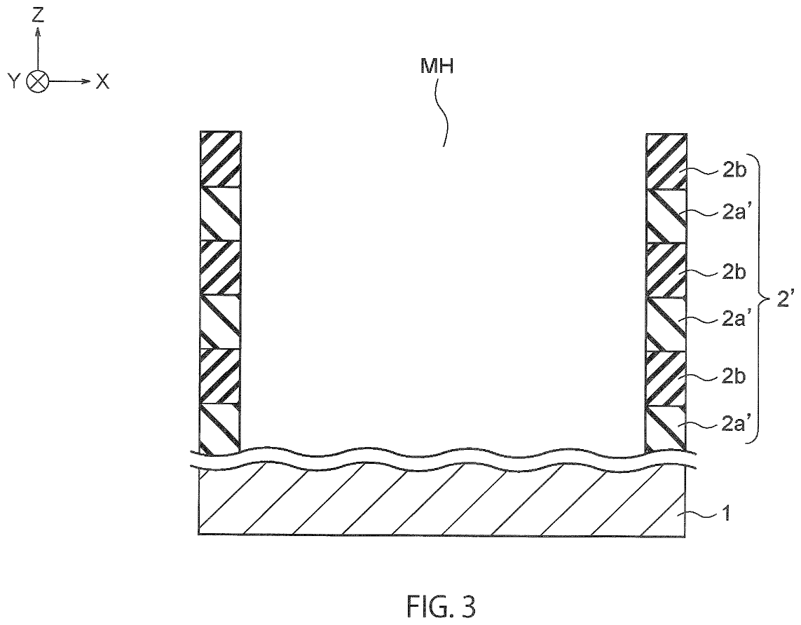

Next, by photolithography and RIE (Reactive Ion Etching), a plurality of memory holes MHs are formed in the stacked film 2′ (FIG. 3). FIG. 3 illustrates one of the memory holes MHs. The memory holes MHs are formed to pass through the stacked film 2′ using a resist film and a hard mask layer (the polysilicon layer for example) as a mask, for example.

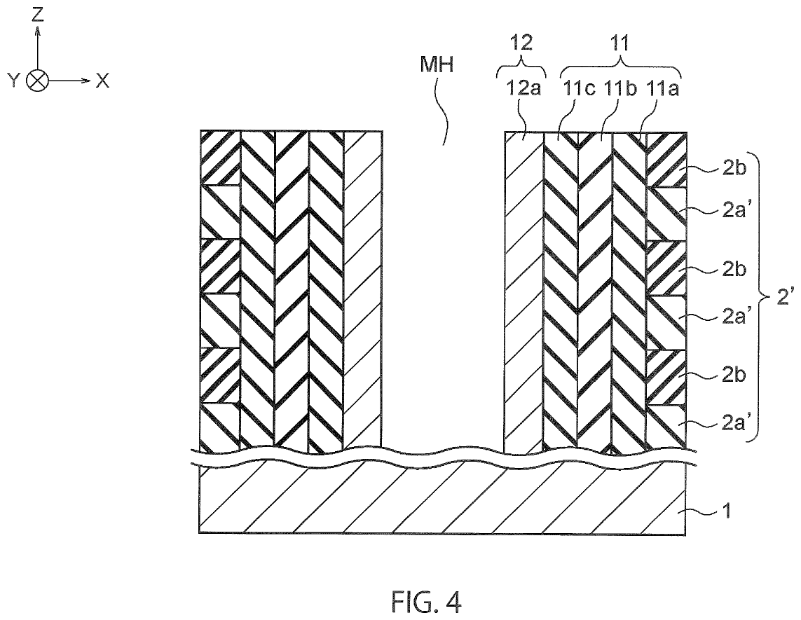

Then, in each memory hole MH, the block insulator 11a, the charge storage layer 11b, the tunnel insulator 11c, and the semiconductor region 12a are formed in order (FIG. 4). As a result, on the side face of the stacked film 2′ in each memory hole MH, the block insulator 11a, the charge storage layer 11b, the tunnel insulator 11c, and the semiconductor region 12a are formed in order. Accordingly, the memory insulator 11 is formed in the memory hole MH. The semiconductor region 12a is the polysilicon layer as described above for example.

The block insulator 11a is formed using TDMAS (Tris(dimethylamino)silane) and O₃ at 400-800° C. and in the decompression environment (2000 Pa or lower) by ALD (“0” denotes oxygen), for example. The charge storage layer 11b is formed using SiH₂Cl₂ and NH₃ at 300-800° C. and in the decompression environment (2000 Pa or lower) by the ALD, for example. The tunnel insulator 11c is formed using HCD (hexachlorodisilane), NH₃ and O₂ at 400-800° C. and in the decompression environment (2000 Pa or lower) by the ALD, for example. The semiconductor region 12a is formed using SiH₄ at 400-800° C. and in the decompression environment (2000 Pa or lower) by the CVD, for example.

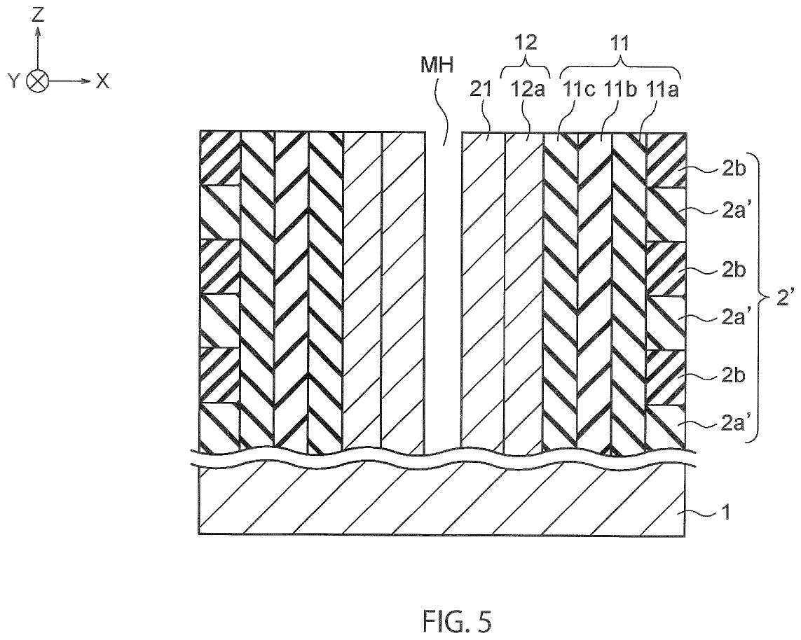

Next, a polymer layer 21 is formed in each memory hole MH (FIG. 5). As a result, the polymer layer 21 is formed on the side face of the semiconductor region 12a in each memory hole MH. The polymer layer 21 is a CF polymer layer including carbon (C) and fluorine (F) for example, and has the thickness of about 5 nm. The polymer layer 21 is an example of a second film.

The polymer layer 21 is formed using a CₓH_{y}F_{z} gas (“x” denotes an integer equal to or larger than 1, “y” denotes an integer equal to or larger than 0, and “z” denotes an integer equal to or larger than 1), for example. The CₓH_{y}F_{z} gas includes the carbon (C) and the fluorine (F) but may or may not include hydrogen (H). The polymer layer 21 of the present embodiment is formed using a C₄F₈ gas. The polymer layer 21 may be formed using liquid instead of the gas.

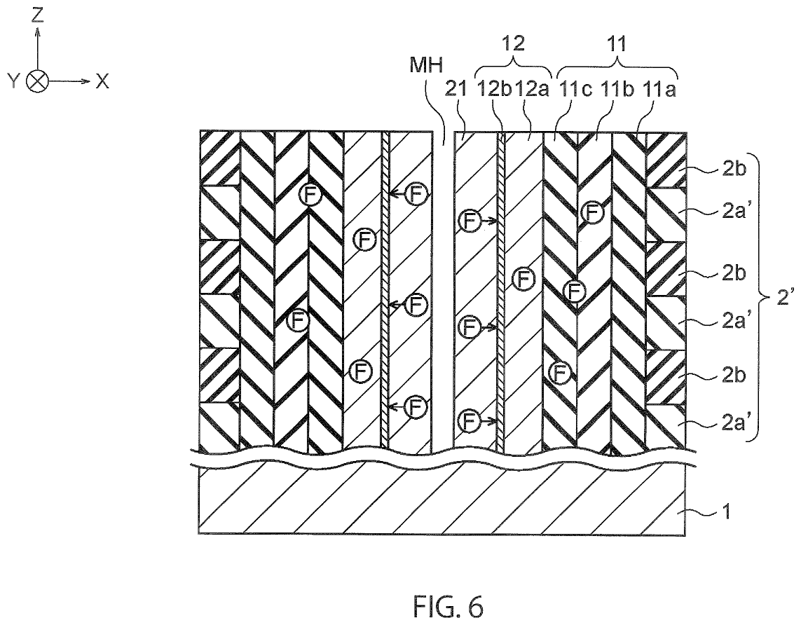

Then, the polymer layer 21, the semiconductor region 12a, the tunnel insulator 11c, the charge storage layer 11b, the block insulator 11a and the like above the substrate 1 are heated by thermal annealing (FIG. 6). As a result, the semiconductor region 12b is formed between the polymer layer 21 and the semiconductor region 12a. Accordingly, the channel semiconductor layer 12 is formed in the memory hole MH. In the present embodiment, by the Si atoms in the semiconductor region 12a and the C atoms in the polymer layer 21, the SiC film is formed as the semiconductor region 12b. Further, the F atoms in the polymer layer 21 are diffused in the semiconductor region 12a, the semiconductor region 12a, the tunnel insulator 11c, the charge storage layer 11b and the block insulator 11a and in the interfaces between them (for example, in the interfaces S1, S2 and S3 illustrated in FIG. 1) by the thermal annealing. FIG. 6 schematically illustrates the F atoms diffused in this way.

The thermal annealing in a process illustrated in FIG. 6 is executed for 30 minutes at 900° C. and under a normal pressure for example. The semiconductor region 12b may be formed in the semiconductor region 12a or may be formed in the polymer layer 21. In addition, the semiconductor region 12b may be formed as the SiC region which is so thin that it cannot be called the SiC film, instead of being formed as the SiC film.

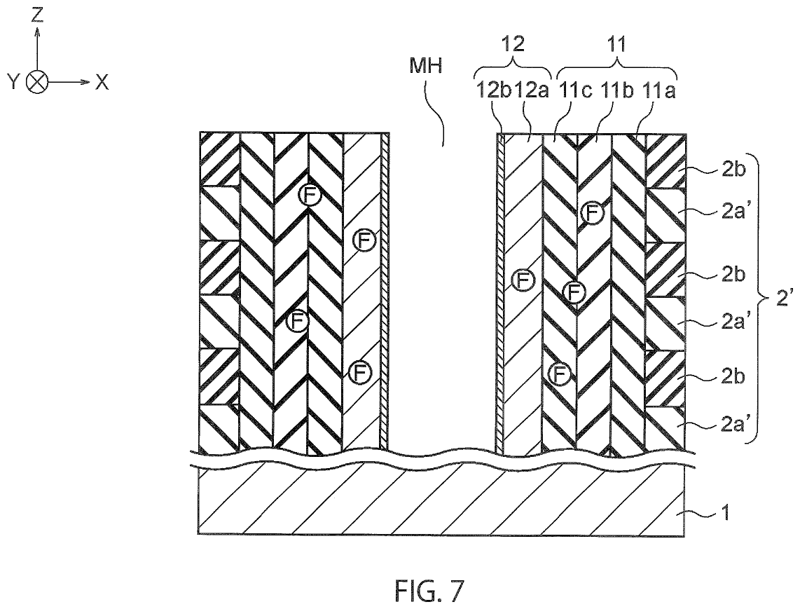

Next, the polymer layer 21 is removed (FIG. 7). As a result, the side face of the semiconductor region 12b is exposed in each memory hole MH. The polymer layer 21 is removed by oxidation of 30 minutes using O₂ at 500° C. and under the normal pressure, for example.

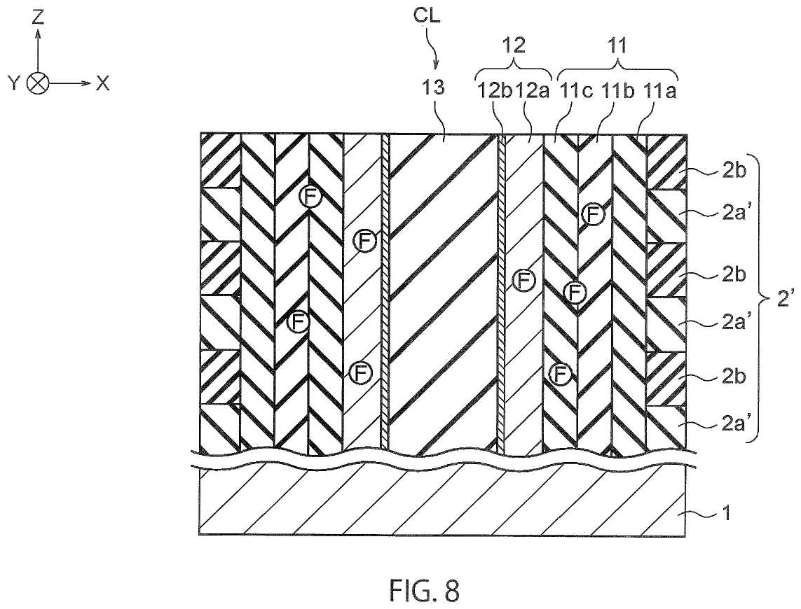

Then, the core insulator 13 is formed in each memory hole MH (FIG. 8). As a result, the core insulator 13 is formed on the side face of the semiconductor region 12b in each memory hole MH. Accordingly, the columnar portion CL is formed in each memory hole MH.

The core insulator 13 is formed using TDMAS and O₃ at 400-800° C. and in the decompression environment (2000 Pa or lower) by the ALD, for example. The core insulator 13 of the present embodiment is formed so as to fill up each memory hole MH.

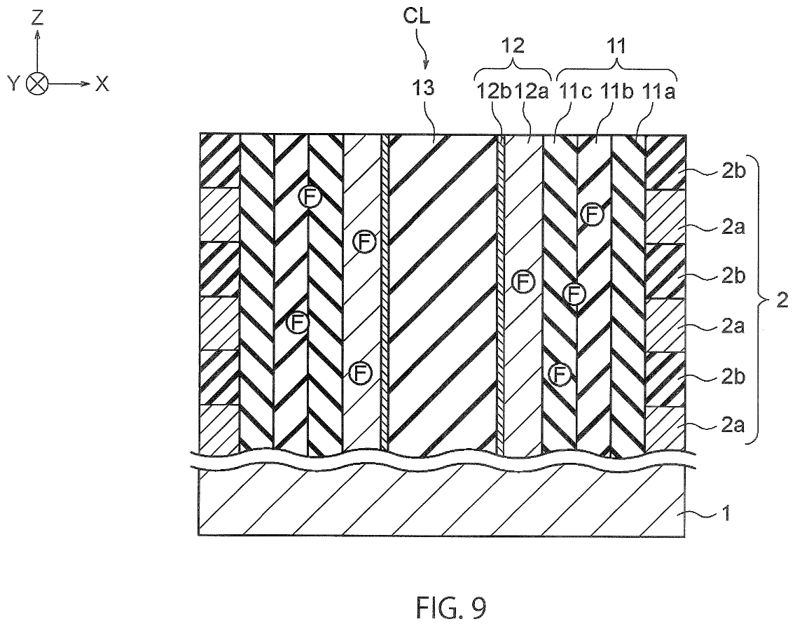

Next, each sacrificing layer 2a′ in the stacked film 2′ is replaced with one electrode layer 2a (FIG. 9). As a result, the stacked film 2 alternately including the plurality of electrode layers 2a and the plurality of insulating layers 2b is formed above the substrate 1. Further, a structure that each columnar portion CL passes through the stacked film 2 is achieved above the substrate 1. In this way, the plurality of cell transistors (memory cells) and the plurality of selection transistors are formed in each columnar portion CL.

The process illustrated in FIG. 9 is executed as follows for example. First, a slit is formed in the stacked film 2′, and each sacrificing layer 2a′ in the stacked film 2′ is selectively removed by hot phosphoric acid using the slit. As a result, a plurality of recesses are formed between the insulating layers 2b in the stacked film 2′. Then, a block insulator, a barrier metal layer and an electrode material layer are formed in order in the recesses. As a result, one electrode layer 2a including the barrier metal layer and the electrode material layer is formed in each recess. The block insulator formed in the process illustrated in FIG. 9 configures the block insulator of each memory cell together with the block insulator 11a formed in the process illustrated in FIG. 4.

In the process illustrated in FIG. 9, the block insulator is an AlOₓ film (aluminum oxide film) for example, and is formed using TMA (trimethylaluminum) and O₃ at 200-500° C. and in the decompression environment (2000 Pa or lower) by the ALD. In addition, the barrier metal layer is a TiN film (titanium nitride film) for example, and is formed using TiCl and NH₃ in the decompression environment by the CVD. Further, the electrode material layer is the W (tungsten) layer for example, and is formed using WF₆ in the decompression environment by the CVD.

In the process illustrated in FIG. 2, instead of forming the stacked film 2′ alternately including the plurality of sacrificing layers 2a′ and the plurality of insulating layers 2b, the stacked film 2 alternately including the plurality of electrode layers 2a and the plurality of insulating layers 2b may be formed. In this case, there is no need to replace the sacrificing layers 2a′ with the electrode layers 2a in the process in FIG. 9. The electrode layers 2a in this case are the examples of the first films.

Thereafter, various interconnect layers, plug layers, inter layer dielectrics or the like are formed above the substrate 1. In this way, the semiconductor device in FIG. 1 is manufactured.

Next, the further details of the method of manufacturing the semiconductor device of the present embodiment will be described.

The core insulator 13 of the present embodiment is not directly formed on the side face of the semiconductor region 12a (Si layer), but is formed on the side face of the semiconductor region 12a via the semiconductor region 12b (SiC film). In the case of directly forming the core insulator 13 on the side face of the semiconductor region 12a, there is a risk that the semiconductor region 12a is oxidized by O atoms for forming the core insulator 13. In this case, when the thickness of the semiconductor region 12a is reduced by high integration of the semiconductor device, there is a risk that an oxidized portion of the semiconductor region 12a passes through the semiconductor region 12a and lowers performance of the channel semiconductor layer 12. On the other hand, in the case of forming the core insulator 13 on the side face of the semiconductor region 12a via the semiconductor region 12b, the semiconductor region 12b is not easily oxidized compared to the semiconductor region 12a. Therefore, the present embodiment makes it possible to suppress problems due to the oxidation of the semiconductor region 12a.

FIG. 9 illustrates the semiconductor region 12b remaining between the semiconductor region 12a and the core insulator 13. When the semiconductor region 12b is the SiC film (or the SiC region), it is possible to increase a thermal process when forming the core insulator 13. This makes it possible to diffuse the F atoms farther. The finished semiconductor device in the present embodiment includes the F atoms in the semiconductor region 12a, the tunnel insulator 11c, the charge storage layer 11b and the block insulator 11a and in the interfaces S1, S2 and S3 between them, for example. The F atoms are sometimes segregated in the interfaces S1, S2 and S3 between them further. The F atoms in each columnar portion CL can terminate the defects and the dangling bonds and improve an electrical characteristic of each columnar portion CL, for example. For example, the F atoms in the channel semiconductor layer 12 can improve carrier mobility, increase a memory cell current, and suppress diffusion to the outside of p-type impurity atoms or n-type impurity atoms in the channel semiconductor layer 12. In addition, the F atoms in the tunnel insulator 11c can suppress stress degradation of the tunnel insulator 11c. Further, the F atoms in the charge storage layer 11b can increase a charge storage amount of the charge storage layer 11b. Furthermore, the F atoms in the block insulator 11a can repair the defects or the like in the block insulator 11a.

Further, the F atoms near the interface between the core insulator 13 and the channel semiconductor layer 12 can reduce scattering of a carrier in the interface and improve the carrier mobility. In addition, the F atoms in the interface S3 of the channel semiconductor layer 12 and the tunnel insulator 11c, the F atoms in the interface S2 of the tunnel insulator 11c and the charge storage layer 11b and the F atoms in the interface S1 of the charge storage layer 11b and the block insulator 11a can repair the defects or the like in the interfaces S3, S2 and S1. It is similar for the F atoms in the interface between the block insulator 11a and each electrode layer 2a.

The sacrificing layer 2a′ may be something other than the SiN film when an etching selection ratio with the insulating layer 2b can be high. An example of such a sacrificing layer 2a′ is the polysilicon layer. In addition, the block insulator 11a may be something other than the SiO₂ film, and may be a stacked film including the SiO₂ film and the SiN film or a high-k film for example. Further, the tunnel insulator 11c may be something other than the SiON film, and may be the SiO₂ film or the high-k film for example. In addition, each electrode layer 2a may include the barrier metal layer (a TaN film (tantalum nitride film) for example) other than the TiN film, or may include the electrode material layer (the polysilicon layer or a silicide layer for example) other than the W layer.

In addition, at least one of the block insulator 11a, the charge storage layer 11b, the tunnel insulator 11c, the semiconductor region 12a and the polymer layer 21 may be formed using a gas other than the above-described gas. For example, the semiconductor region 12a may be formed using a SiH₄ gas and a Si₂H₆ gas alternately. Further, the polymer layer 21 may be formed using a C₃F₆ gas.

As above, the channel semiconductor layer 12 of the present embodiment is formed to include the semiconductor region 12a including silicon (Si) and the semiconductor region 12b including silicon (Si) and the carbon (C). Therefore, the present embodiment makes it possible to improve the performance of the channel semiconductor layer 12 as described above. Further, it is also possible to improve the performance of the other parts in each columnar portion CL as described above.

### Second Embodiment

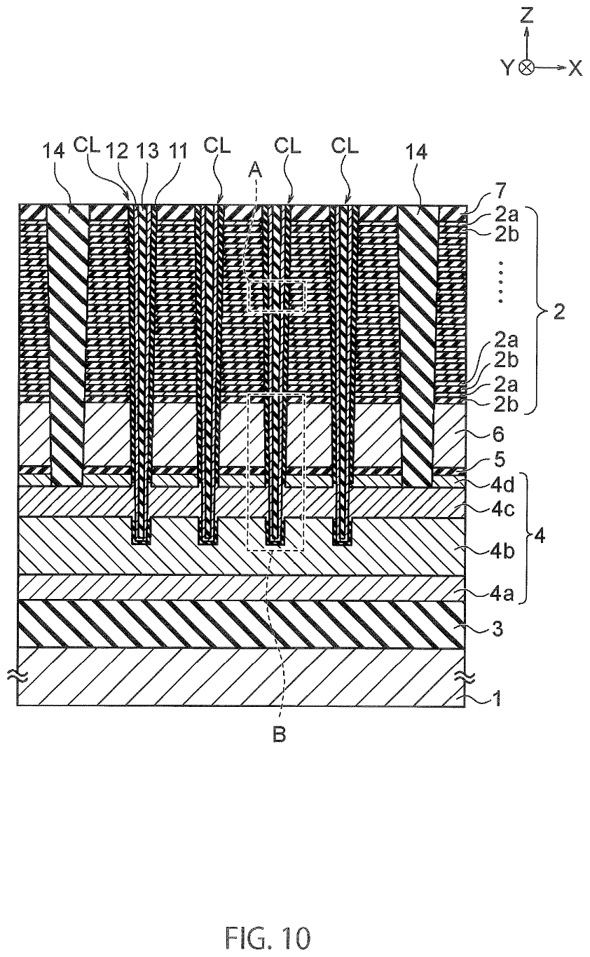

FIG. 10 is a sectional view illustrating a structure of a semiconductor device of the second embodiment. The semiconductor device in FIG. 10 is a three-dimensional memory for example.

The semiconductor device in FIG. 10 includes the substrate 1 and the stacked film 2, similarly to the semiconductor device in FIG. 1. In addition, the semiconductor device in FIG. 10 includes an inter layer dielectric 3, a source layer 4, an inter layer dielectric 5, a gate layer 6, and an inter layer dielectric 7. The stacked film 2 includes the plurality of electrode layers 2a and the plurality of insulating layers 2b. The source layer 4 includes a metal layer 4a, a lower semiconductor layer 4b, a middle semiconductor layer 4c, and an upper semiconductor layer 4d.

The semiconductor device in FIG. 10 further includes the plurality of columnar portions CLs. The columnar portions CLs in FIG. 10 each include the memory insulator 11, the channel semiconductor layer 12, and the core insulator 13, similarly to the columnar portion CL in FIG. 1. In addition, the semiconductor device in FIG. 10 includes a plurality of isolation insulators 14. The substrate 1 is a semiconductor substrate such as an Si substrate as described above, for example. The inter layer dielectric 3, the source layer 4, the inter layer dielectric 5, and the gate layer 6 are formed on the substrate 1 in order. The inter layer dielectric 3 is the SiO₂ film, for example. The source layer 4 includes the metal layer 4a (the W layer for example), the lower semiconductor layer 4b (the polysilicon layer for example), the middle semiconductor layer 4c (the polysilicon layer for example), and the upper semiconductor layer 4d (the polysilicon layer for example) formed on the inter layer dielectric 3 in order. The inter layer dielectric 5 is the SiO₂ film, for example. The gate layer 6 is the polysilicon layer, for example.

The stacked film 2 includes the plurality of electrode layers 2a and the plurality of insulating layers 2b alternately stacked on the gate layer 6. The electrode layers 2a each include the metal layer such as the W layer as described above, for example. The insulating layers 2b each are the SiO₂ film as described above, for example. The inter layer dielectric 7 is formed on the stacked film 2. The inter layer dielectric 7 is the SiO₂ film, for example.

The columnar portions CL each include the memory insulator 11, the channel semiconductor layer 12 and the core insulator 13 formed in order in the lower semiconductor layer 4b, the middle semiconductor layer 4c, the upper semiconductor layer 4d, the inter layer dielectric 5, the gate layer 6, the stacked film 2 and the inter layer dielectric 7, and have the columnar shape extending in the Z direction. The channel semiconductor layer 12 of the present embodiment is in contact with the middle semiconductor layer 4c as illustrated in FIG. 10, and is electrically connected to the source layer 4.

The isolation insulators 14 each are formed in order in the upper semiconductor layer 4d, the inter layer dielectric 5, the gate layer 6, the stacked film 2 and the inter layer dielectric 7, and have a planar shape extending in the Z direction and the Y direction. The isolation insulators 14 each are the SiO₂ film, for example.

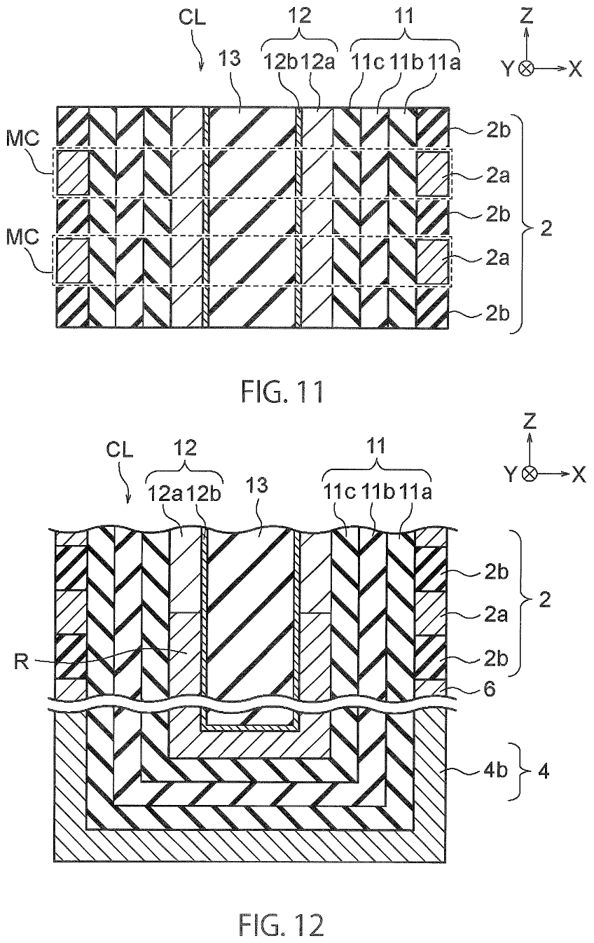

FIG. 11 is an enlarged sectional view illustrating the structure of the semiconductor device of the second embodiment, and illustrates a region A in FIG. 10.

The columnar portions CLs of the present embodiment each include the block insulator 11a, the charge storage layer 11b and the tunnel insulator 11c of the memory insulator 11, the semiconductor region 12a and the semiconductor region 12b of the channel semiconductor layer 12 and the core insulator 13 in order, as illustrated in FIG. 11. The block insulator 11a is the SiO₂ film, for example. The charge storage layer 11b is the SiN film, for example. The tunnel insulator 11c is the SiON film, for example. The semiconductor region 12a is the polysilicon layer, for example. The semiconductor region 12b is the SiC film, for example. The core insulator 13 is the SiO₂ film, for example. The stacked film 2 includes the plurality of electrode layers 2a and the plurality of insulating layers 2b as described above, and the electrode layers 2a configure a plurality of memory cells MCs or the like together with each columnar portion CL.

FIG. 12 is another enlarged sectional view illustrating the structure of the semiconductor device of the second embodiment, and illustrates a region B in FIG. 10.

The columnar portions CLs of the present embodiment each include an impurity diffusion region R in the semiconductor region 12a, as illustrated in FIG. 12. The impurity diffusion region R is provided in a lower end portion of the semiconductor region 12a. The impurity diffusion region R includes n-type impurities or p-type impurities, and is used to generate a GIDL (Gate Induced Drain Leakage) current for deleting storage data in a memory MC. The side face of the impurity diffusion region R is in contact with the side faces of the middle semiconductor layer 4c and the tunnel insulator 11c. The impurity diffusion region R is an example of a third semiconductor region.

Each columnar portion CL of the present embodiment includes the F atoms, similarly to each columnar portion CL of the first embodiment. For example, the F atoms in the impurity diffusion region R can suppress the diffusion in the Z direction in the semiconductor region 12a of impurities in the impurity diffusion region R. This makes it possible to suppress reduction of the GIDL current due to the diffusion of the impurities. Also, it becomes possible to suppress threshold dispersion of the selection transistor due to the diffusion of the impurities and reduce occurrence of short-circuit defects of the selection transistor due to the diffusion of the impurities, and improvement in a yield of the semiconductor device can be expected. The columnar portions CLs of the present embodiment each include the C atoms in addition to the F atoms. This makes it possible to further suppress the diffusion of the impurities. The impurities are P (phosphorous) atoms for example.

In the present embodiment, the concentration of the impurities in the impurity diffusion region R is biased along the Z direction. For example, the concentration of the impurities is high at a height of the middle semiconductor layer 4c, and the concentration of the impurities lowers as departing from the height of the middle semiconductor layer 4c at the heights different from the height of the middle semiconductor layer 4c. On the other hand, the concentration of the C atoms and the F atoms in the impurity diffusion region R does not change so much along the Z direction. For example, the concentration of the C atoms and the F atoms in the impurity diffusion region R is substantially same at the height of the lower semiconductor layer 4b, the height of the middle semiconductor layer 4c and the height of the upper semiconductor layer 4d. Therefore, oxidation suppression in the semiconductor region 12a and termination of the defects and the dangling bonds of the columnar portions CLs by the C atoms and the F atoms are effective to the whole columnar portions CLs independent of the Z direction of the columnar portions CLs. The present embodiment makes it possible to maintain the concentration of the impurities in the impurity diffusion region R at the height of the middle semiconductor layer 4c at the high concentration by such C atoms and F atoms, in addition to suppressing the oxidation in the semiconductor region 12a and terminating the defects and the dangling bonds of the columnar portions CLs. The concentration of the P atoms in the impurity diffusion region R at the height of the middle semiconductor layer 4c is about 1.0×10²¹ cm⁻³ for example. The concentration of the P atoms in the impurity diffusion region R can be calculated from a resistance value of the impurity diffusion region R, for example.

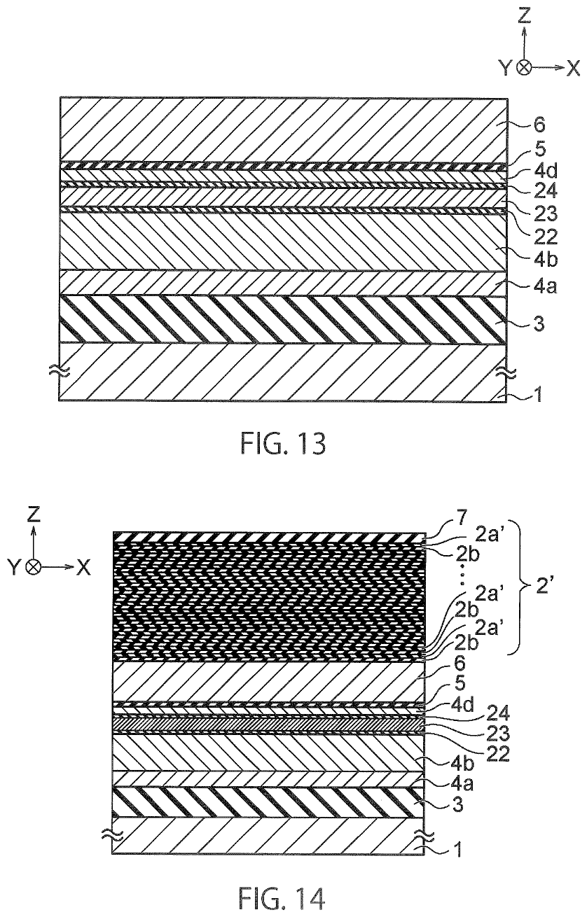

FIGS. 13 to 26 are sectional views illustrating a method of manufacturing the semiconductor device of the second embodiment.

First, on the substrate 1, the inter layer dielectric 3, the metal layer 4a, the lower semiconductor layer 4b, a lower protective film 22, a sacrificing layer 23, an upper protective film 24, the upper semiconductor layer 4d, the inter layer dielectric 5, and the gate layer 6 are formed in order (FIG. 13). The lower protective film 22 is the SiO₂ film, for example. The sacrificing layer 23 is the polysilicon layer, for example. The upper protective film 24 is the SiO₂ film, for example.

Next, the stacked film 2′ alternately including the plurality of sacrificing layers 2a′ and the plurality of insulating layers 2b is formed on the gate layer 6, and the inter layer dielectric 7 is formed on the stacked film 2′ (FIG. 14). The sacrificing layers 2a′ each are the SiN film as described above, for example. The sacrificing layers 2a′ are replaced with the plurality of electrode layers 2a by the process to be described later. In the case of adopting a procedure of omitting the process to be described later, the electrode layers 2a are formed instead of the sacrificing layers 2a′ in the process in FIG. 14.

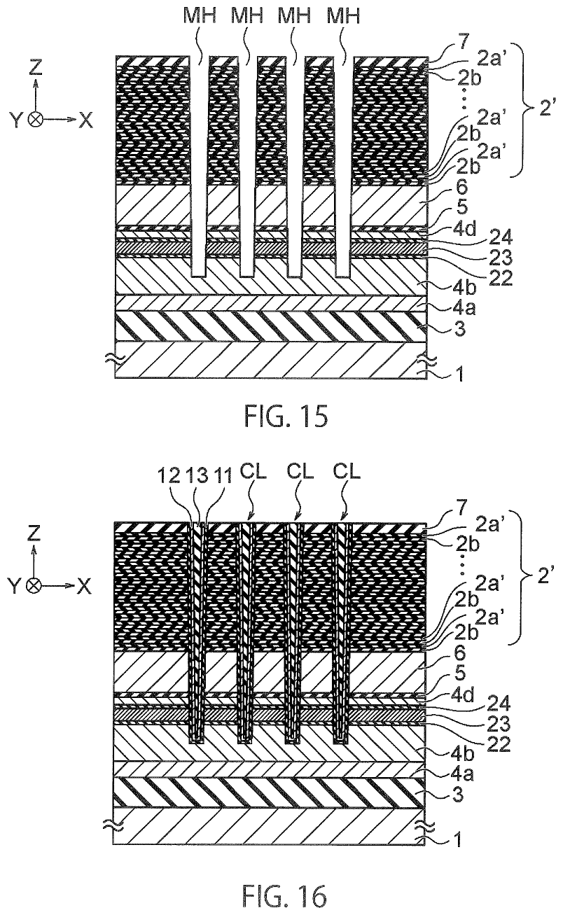

Then, by the photolithography and the RIE, the plurality of memory holes MHs are formed in the inter layer dielectric 7, the stacked film 2′, the gate layer 6, the inter layer dielectric 5, the upper semiconductor layer 4d, the upper protective film 24, the sacrificing layer 23, the lower protective film 22, and the lower semiconductor layer 4b (FIG. 15).

Subsequently, in the memory holes MHs, the memory insulator 11, the channel semiconductor layer 12, and the core insulator 13 are formed in order (FIG. 16). As a result, the plurality of columnar portions CLs are formed in the memory holes MHs. The memory insulator 11 is formed by forming the block insulator 11a, the charge storage layer 11b and the tunnel insulator 11c described above in order in each memory hole MH. In addition, the channel semiconductor layer 12 is formed so as to include the semiconductor region 12a and the semiconductor region 12b described above in order by performing the processes illustrated in FIG. 4 to FIG. 7.

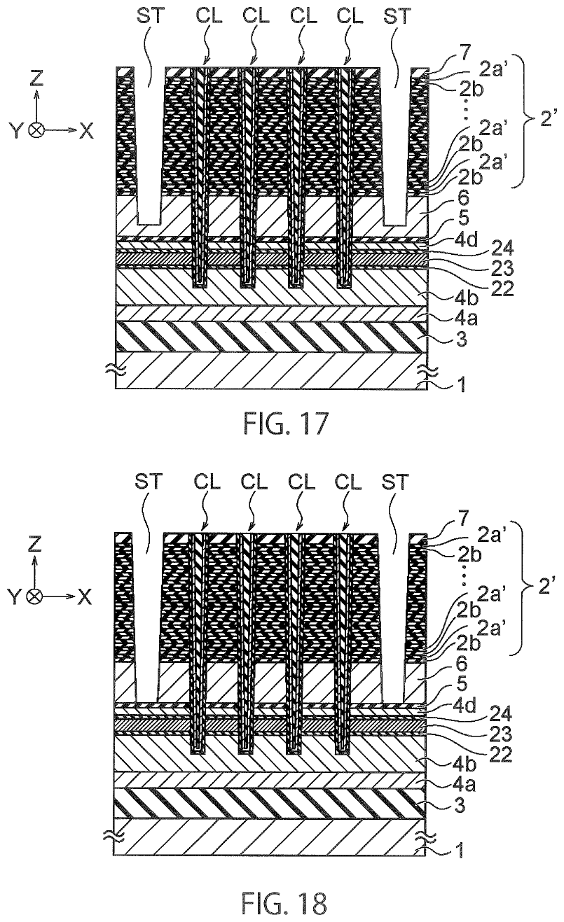

Next, by the photolithography and the RIE, a plurality of isolation trenches (slits) STs are formed in the inter layer dielectric 7, the stacked film 2′ and the gate layer 6 (FIG. 17 and FIG. 18). The RIE is performed using a first etching gas in the process illustrated in FIG. 17, and is performed using a second etching gas different from the first etching gas in the process illustrated in FIG. 18.

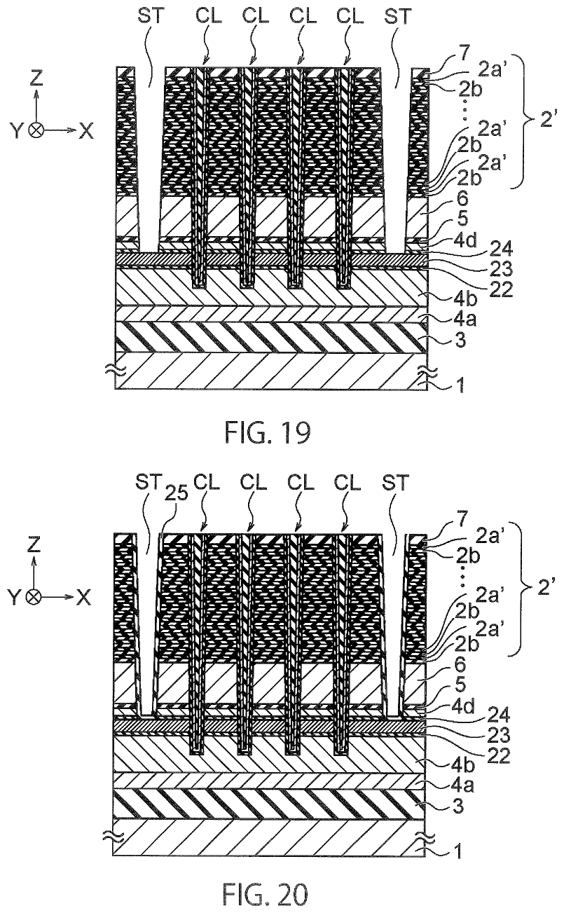

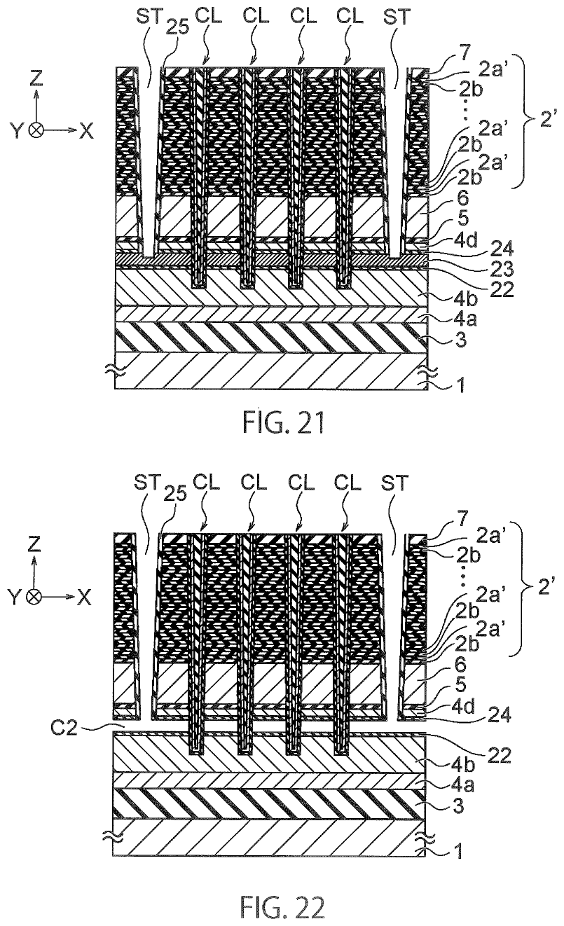

Then, the upper protective film 24 is removed from bottom surfaces of the isolation trenches STs by etching (FIG. 19), a liner layer 25 is formed on surfaces of the isolation trenches STs (FIG. 20), and the liner layer 25 is removed from the bottom surfaces of the isolation trenches STs by etching (FIG. 21). As a result, the side faces of the isolation trenches STs are protected by the liner layer 25, and the sacrificing layer 23 is exposed to the bottom surfaces of the isolation trenches STs on the other hand. The liner layer 25 is the SiN film, for example.

Thereafter, by wet etching using the isolation trenches STs, the sacrificing layer 23 is removed (FIG. 22). As a result, a cavity (air gap) C2 is formed between the lower protective film 22 and the upper protective film 24, and the memory insulator 11 is exposed to the side face of the cavity C2.

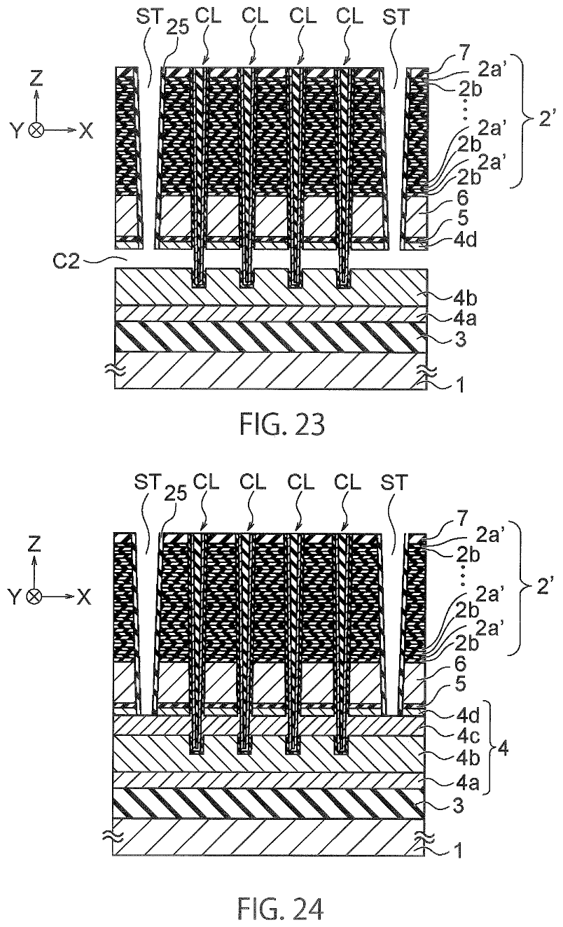

Next, by CDE (Chemical Dry Etching) using the isolation trenches STs, the lower protective film 22, the upper protective film 24 and the memory insulator 11 exposed to the side face of the cavity C2 are removed (FIG. 23). As a result, the upper semiconductor layer 4d is exposed to an upper surface of the cavity C2, the lower semiconductor layer 4b is exposed to a lower surface of the cavity C2, and the channel semiconductor layer 12 is exposed to the side face of the cavity C2.

Then, by forming the middle semiconductor layer 4c on the surfaces of the upper semiconductor layer 4d, the lower semiconductor layer 4b and the channel semiconductor layer 12 exposed in the cavity C2, the middle semiconductor layer 4c is formed in the cavity C2 (FIG. 24). As a result, the middle semiconductor layer 4c in contact with the upper semiconductor layer 4d, the lower semiconductor layer 4b and the channel semiconductor layer 12 is formed between the upper semiconductor layer 4d and the lower semiconductor layer 4b. By thermal treatment when forming the middle semiconductor layer 4c or thermal treatment in the subsequent process, the impurities in the middle semiconductor layer 4c are thermally diffused. The present embodiment makes it possible to suppress the diffusion of the impurities in the middle semiconductor layer 4c since the columnar portions CLs include the F atoms and the C atoms.

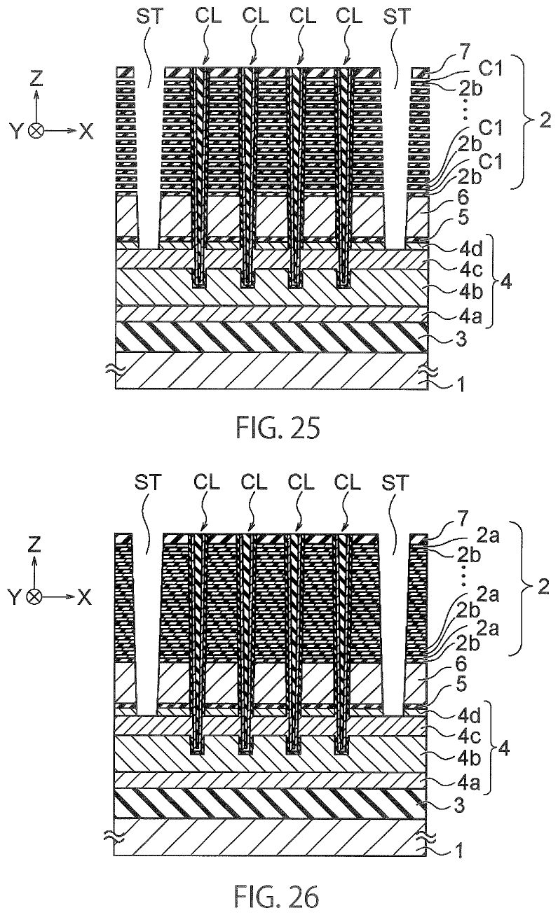

Next, by wet etching or dry etching using the isolation trenches STs, the liner layer 25 in the isolation trenches STs and each sacrificing layer 2a′ in the stacked film 2′ are removed (FIG. 25). As a result, a plurality of cavities (air gaps) C1 are formed between the insulating layers 2b in the stacked film 2′. Subsequently, by the CVD, the plurality of electrode layers 2a are formed in the cavities C1 (FIG. 26). As a result, the stacked film 2 alternately including the plurality of electrode layers 2a and the plurality of insulating layers 2b is formed between the gate layer 6 and the inter layer dielectric 7.

Thereafter, the isolation insulators 14 are formed in the isolation trenches STs. Further, various plug layers, interconnect layers and inter layer dielectrics or the like are formed on the substrate 1. In this way, the semiconductor device in FIG. 10 is manufactured.

As above, the channel semiconductor layer 12 of the present embodiment is formed to include the semiconductor region 12a including the silicon (Si) and the semiconductor region 12b including the silicon (Si) and the carbon (C), similarly to the channel semiconductor layer 12 of the first embodiment. Therefore, the present embodiment makes it possible to improve the performance of the channel semiconductor layer 12 as described above. Further, it is also possible to improve the performance of the other parts in each columnar portion CL as described above.

### Third Embodiment

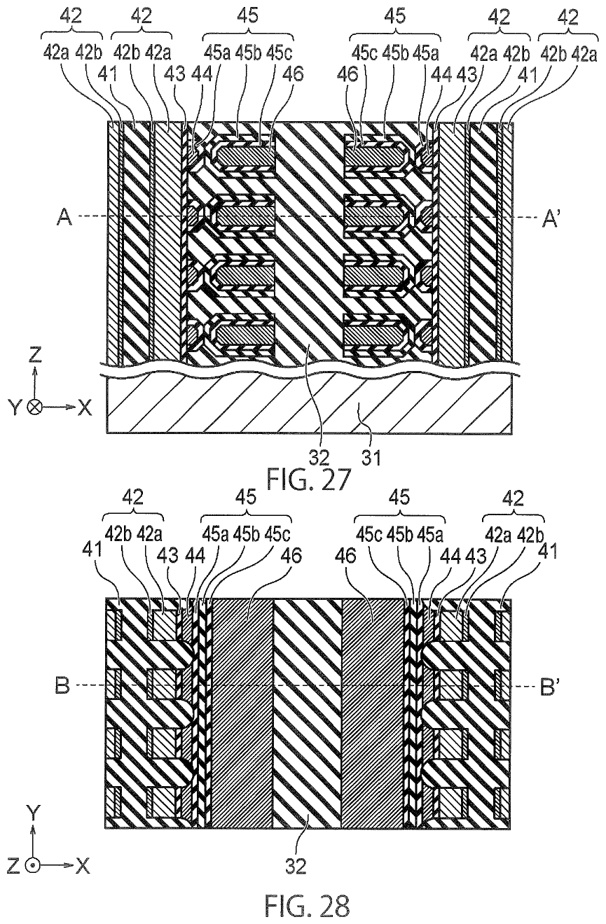

FIG. 27 and FIG. 28 are sectional views illustrating a structure of a semiconductor device of the third embodiment.

FIG. 27 illustrates a longitudinal section (XZ section) of the semiconductor device of the present embodiment. FIG. 28 illustrates a cross section (XY section) of the semiconductor device of the present embodiment. FIG. 27 illustrates the longitudinal section along a B-B′ line in FIG. 28, and FIG. 28 illustrates the cross section along an A-A′ line in FIG. 27. The semiconductor device of the present embodiment is a three-dimensional memory for example.

Hereinafter, the structure of the semiconductor device of the present embodiment will be described mainly with reference to FIG. 27. In the description, FIG. 28 is also appropriately referred to.

The semiconductor device of the present embodiment includes, as illustrated in FIG. 27, a substrate 31, an inter layer dielectric 32, a plurality of core insulators 41, a plurality of channel semiconductor layers 42, a plurality of tunnel insulators 43, a plurality of charge storage layers (floating gates) 44, block insulators 45, and a plurality of electrode layers (control gates) 46. The channel semiconductor layers 42 each include semiconductor regions 42a and 42b. The block insulators 45 each include insulators 45a, 45b and 45c. The block insulator 45 is an example of the first insulator, and the tunnel insulator 43 is an example of the second insulator. The semiconductor region 42a is an example of the first semiconductor region, and the semiconductor region 42b is an example of the second semiconductor region.

The substrate 31 is a semiconductor substrate such as an Si substrate, for example. FIG. 27 illustrates, similarly to FIG. 1 to FIG. 26, the X direction and the Y direction parallel to the surface of the substrate 31 and perpendicular to each other, and the Z direction perpendicular to the surface of the substrate 31. The Z direction is an example of the first direction. The Y direction is an example of the second direction.

The inter layer dielectric 32 is formed on the substrate 31. The inter layer dielectric 32 is the SiO₂ film, for example.

The core insulators 41, the channel semiconductor layers 42, the tunnel insulators 43, the charge storage layers 44, the block insulators 45, and the electrode layers 46 are formed in the inter layer dielectric 32 on the substrate 31. The core insulators 41 are the SiO₂ film, for example. The semiconductor regions 42a and 42b of the channel semiconductor layers 42 are the polysilicon layer and the SiC film respectively, for example. The tunnel insulators 43 are the SiO₂ film, for example. The charge storage layers 44 are the polysilicon layer, for example. The insulators 45a, 45b and 45c of the block insulators 45 are the SiN film, the SiO₂ film, and the SiN film respectively, for example. The electrode layers 46 are the metal layer including the W layer, for example.

The electrode layers 46 each have a belt-like shape extending in the Y direction (FIG. 27 and FIG. 28). FIG. 27 illustrates a plurality of sets (two sets in this case) of electrode layer arrays where the plurality of electrode layers 46 are lined up in the Z direction, and each electrode layer array includes the plurality (four pieces in this case) of electrode layers 46 separated from each other and arranged in a one-dimensional array shape in the Z direction. The number of the electrode layers 46 in each electrode layer array is not limited to four.

Each charge storage layer 44 is provided on the side face of the corresponding electrode layer 46 via the corresponding block insulator 45 (FIG. 27 and FIG. 28). The insulators 45c and 45b are formed in order on the upper surface, the lower surface and the side face of the corresponding electrode layer 46, as illustrated in FIG. 27. On the other hand, the insulator 45a is formed on the upper surface, the lower surface and the side face of the corresponding charge storage layer 44, as illustrated in FIG. 27. FIG. 27 and FIG. 28 illustrate a plurality of sets (two sets in this case) of charge storage layer arrays where the plurality of charge storage layers 44 are lined up in the Z direction and the Y direction, and each charge storage layer array includes the plurality (16 pieces in this case) of charge storage layers 44 separated from each other and arranged in a two-dimensional array shape in the Z direction and the Y direction. The number of the charge storage layers 44 in each charge storage layer array is not limited to 16.

Each channel semiconductor layer 42 is provided on the side faces of the plurality of corresponding charge storage layers 44 via the corresponding tunnel insulator 43 (FIG. 27 and FIG. 28). The semiconductor regions 42a and 42b are formed in order on the side faces of the plurality of corresponding charge storage layers 44 via the corresponding tunnel insulator 43. Each channel semiconductor layer 42 has a columnar shape extending in the Z direction, as illustrated in FIG. 27 and FIG. 28. FIG. 28 illustrates a plurality of sets (four sets in this case) of channel semiconductor layer arrays where the plurality of channel semiconductor layers 42 are lined up in the Y direction, and each channel semiconductor layer array includes the plurality (four pieces in this case) of channel semiconductor layers 42 separated from each other and arranged in the one-dimensional array shape in the Y direction. The number of the channel semiconductor layers 42 in each channel semiconductor layer array is not limited to four.

Each core insulator 41 is arranged between two sets of the corresponding channel semiconductor layer arrays, and is provided on the side face of each channel semiconductor layer 42 in the channel semiconductor layer arrays (FIG. 27 and FIG. 28). Each core insulator 41 has a roughly planar shape extending in the Z direction and the Y direction, as illustrated in FIG. 27 and FIG. 28.

In the present embodiment, each channel semiconductor layer 42 extends in the Z direction, and each electrode layer 46 extends in the Y direction. Then, each charge storage layer 44 of the present embodiment is provided in an intersection portion of one corresponding channel semiconductor layer 42 and one corresponding electrode layer 46. As a result, arrangement of the charge storage layers 44 in a two-dimensional matrix shape is achieved.

The semiconductor device of the present embodiment can be manufactured by a method similar to the method of manufacturing the semiconductor device of the first or second embodiment. For example, when forming the semiconductor regions 42a and 42b of the channel semiconductor layer 42, the processes illustrated in FIG. 4 to FIG. 7 are performed similarly to the time of forming the semiconductor regions 12a and 12b of the channel semiconductor layer 12. This makes it possible to introduce the F atoms into the channel semiconductor layers 42, the tunnel insulators 43, the charge storage layers 44, the block insulators 45 and the electrode layers 46 and into the interfaces between them.

As above, the channel semiconductor layers 42 of the present embodiment are formed to include the semiconductor region 42a including the silicon (Si) and the semiconductor region 42b including the silicon (Si) and the carbon (C), similarly to the channel semiconductor layer 12 of the first and second embodiments. Therefore, the present embodiment makes it possible to improve the performance of the channel semiconductor layers 42 and the other parts similarly to the cases of the first and second embodiments.

### Fourth Embodiment

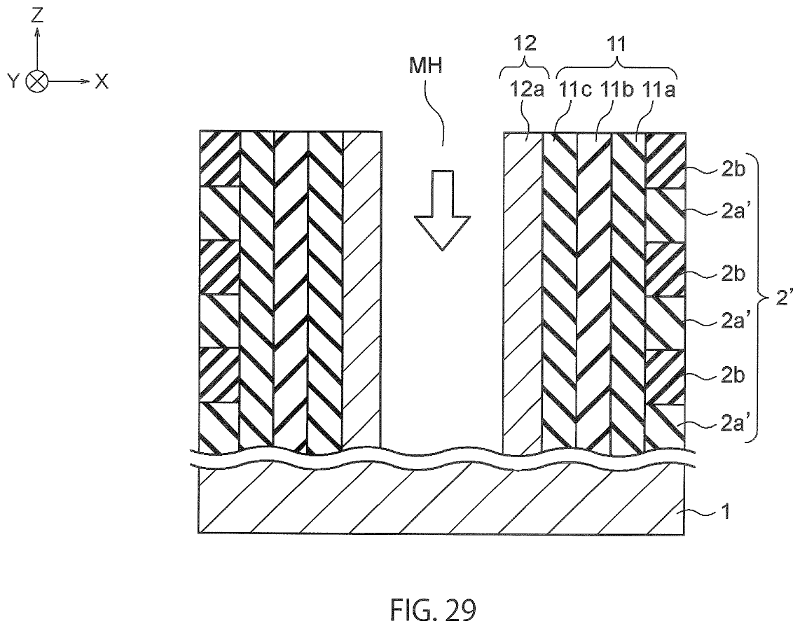

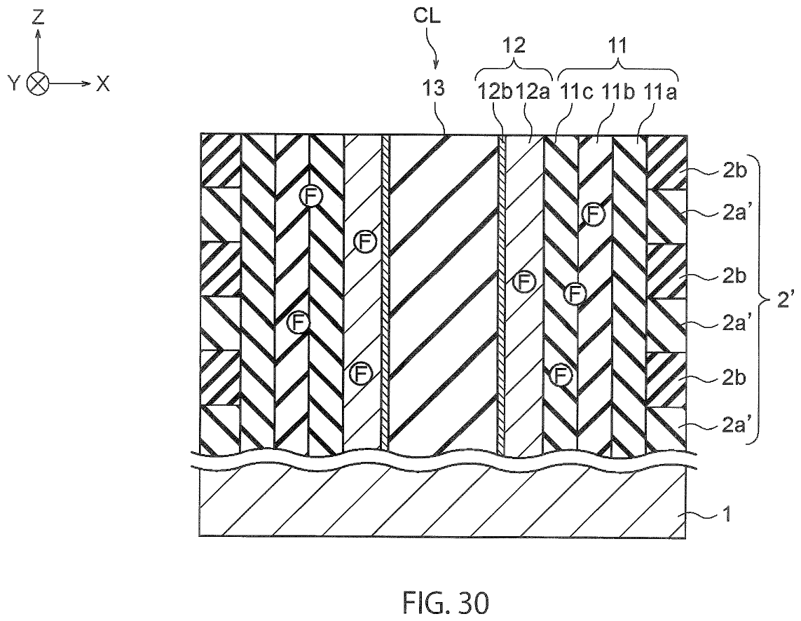

FIGS. 29 and 30 are sectional views illustrating a method of manufacturing a semiconductor device of the fourth embodiment.

First, after executing the processes illustrated in FIG. 2 to FIG. 4, a fluorine additive is supplied into each memory hole MH (FIG. 29). As a result, the fluorine additive is attached to the side face of the semiconductor region 12a in each memory hole MH.

The fluorine additive may be a gaseous substance or a liquid substance. The fluorine additive of the present embodiment is the liquid substance for example, and is applied to the side face of the semiconductor region 12a in each memory hole MH. In addition, the fluorine additive of the present embodiment is a substance including at least the fluorine (F) and the carbon (C), for example, and has a functional group capable of forming a chemical bond with the surface of the semiconductor region 12a. The functional group is a silyl group, for example. In the present embodiment, as the fluorine additive, a silylating agent to which the fluorine is introduced by fluorination is used. A fluorine content and a carbon content of the fluorine additive are adjustable by changing a composition of a substituent group for example.

The fluorine additive may have a functional group other than the silyl group, and may have a functional group capable of forming an ionic bond with the surface of the semiconductor region 12a for example. Examples of such a functional group are a sulfone group, an amino group, a carboxyl group, and a thiol group. The fluorine additive of the present embodiment is adsorbed to the surface of the semiconductor region 12a by molecules of the fluorine additive turning to cations or anions since the hydrogen bonds with the moles of the fluorine additive or the hydrogen leaves the moles of the fluorine additive.

The semiconductor region 12a of the present embodiment is the polysilicon layer for example, and the surface of the polysilicon layer is air-oxidized. Therefore, the silylating agent is chemisorbed to the side face of the semiconductor region 12a in each memory hole MH. The silylating agent may be physically adsorbed to the side face of the semiconductor region 12a instead of being chemisorbed to the side face of the semiconductor region 12a.

Next, the core insulator 13 is formed on the side face of the semiconductor region 12a in each memory hole MH, and modification annealing of the core insulator 13 and additional annealing thereafter are performed (FIG. 30). As a result, the semiconductor region 12b is formed between the semiconductor region 12a and the core insulator 13, and the F atoms originating from the fluorine additive are diffused in the semiconductor region 12b, the semiconductor region 12a, the tunnel insulator 11c, the charge storage layer 11b and the block insulator 11a and in the interfaces between them. FIG. 30 schematically illustrates the F atoms diffused in this way. In the present embodiment, by the C atoms originating from the fluorine additive, the SiC film is formed as the semiconductor region 12b.

Before performing the modification annealing, the silylating agent is present in the interface between the semiconductor region 12a and the core insulator 13. The silylating agent is decomposed into the C atoms and the F atoms by heat of the modification annealing and the additional annealing. As a result, the C atoms form the semiconductor region 12b as described above, and the F atoms are diffused as described above. This makes it possible to obtain the effects similar to the effects by the SiC film and the F atoms of the first to third embodiments.

Thereafter, the various interconnect layers, plug layers, inter layer dielectrics or the like are formed above the substrate 1. In this way, the semiconductor device of the present embodiment is manufactured.

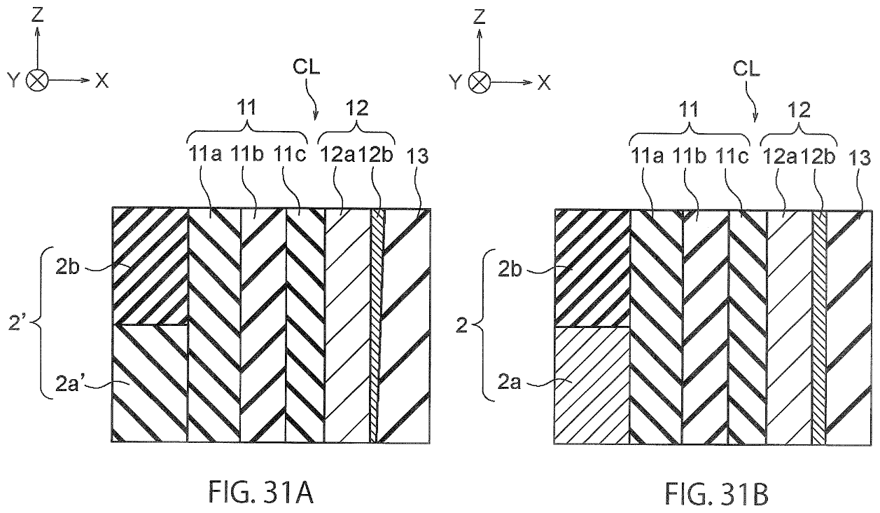

FIGS. 31A and 31B are sectional views for comparing the method of manufacturing the semiconductor device of the first embodiment and the method of manufacturing the semiconductor device of the fourth embodiment.

FIG. 31A illustrates the semiconductor region 12b formed by the method of the first embodiment. In the first embodiment, the polymer layer 21 (FIG. 5) is formed on the side face of the semiconductor region 12a, and the semiconductor region 12b is formed using the polymer layer 21. In this case, when an aspect ratio of the memory hole MH is big, there is a risk that the thickness of each portion of the polymer layer 21 changes according to a depth at which each portion is provided. For example, there is a risk that the thickness of the polymer layer 21 near an upper end of the memory hole MH increases and the thickness of the polymer layer 21 near a lower end of the memory hole MH decreases. As a result, there is a risk that the thickness of the semiconductor region 12b in each columnar portion CL and distribution of the F atoms become nonuniform.

FIG. 31B illustrates the semiconductor region 12b formed by the method of the fourth embodiment. In the fourth embodiment, the semiconductor region 12b is formed by making the fluorine additive be adsorbed to the side face of the semiconductor region 12a. In this case, even when the aspect ratio of the memory hole MH is big, the fluorine additive can be uniformly adsorbed to the side face of the semiconductor region 12a. This makes it possible to easily uniformize the thickness of the semiconductor region 12b in each columnar portion CL and the distribution of the F atoms.

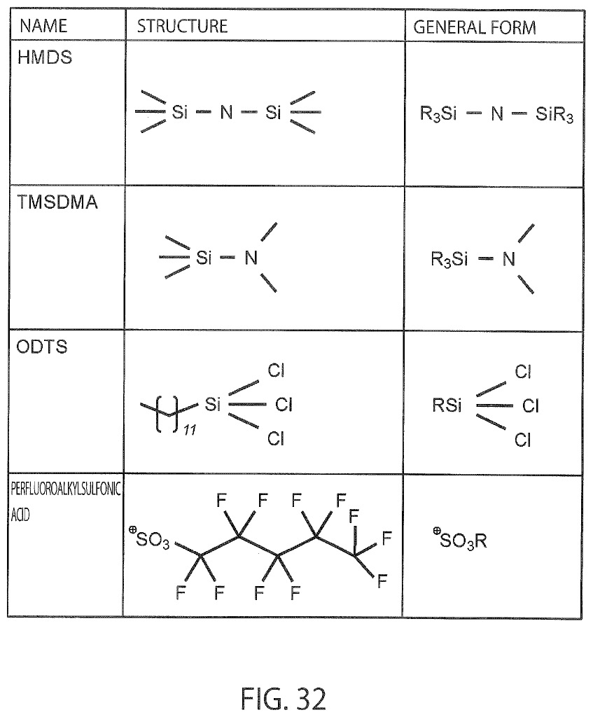

FIG. 32 is a table for describing the fluorine additive of the fourth embodiment.

FIG. 32 illustrates HMDS (hexamethyldisilane), TMSDMA (N-(tetramethylsilyl) dimethylamine), ODTS (octadecyltrichlorosilane), and perfluoroalkylsulfonic acid as concrete examples of the fluorine additive of the present embodiment. FIG. 32 illustrates the structures and general forms of the substances.

The fluorine content of the fluorine additive and a diffusion amount of the F atoms into each columnar portion CL are adjustable by changing the composition of the substituent group of the fluorine additive for example. For example, an alkyl group of organic molecules of the HMDS or the TMSDMA or the like may be substituted with a fluoroalkyl group. In addition, by introducing a reaction point to the substituent group and adjusting the number of times of repeating the application of the fluorine additive, the diffusion amount of the F atoms may be adjusted. At the time, by performing applying treatment of the fluorine additive and modifying treatment by an oxidant (ozone for example), the concentration of the fluorine additive to be adsorbed to the side face of the semiconductor region 12a may be adjusted. Further, the applying treatment of the fluorine additive and the modifying treatment by the oxidant may be alternately and repeatedly performed. Examples of the reaction point are the functional group such as a hydroxyl (OH) group, the amino group, the thiol group or the carboxyl group, the substituent group including an unsaturated bond of an alkylene group or alkynyl group or the like, and a characteristic group of halogen or the like.

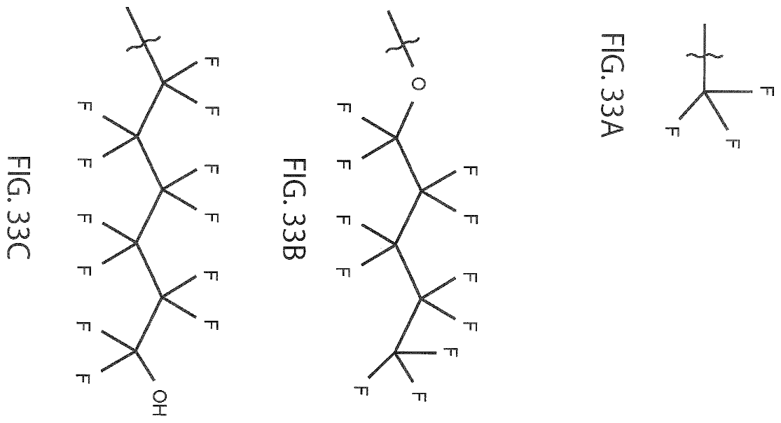

FIGS. 33A to 33C are structural formulas for describing a partial structure of the fluorine additive of the fourth embodiment. Specifically, FIGS. 33A to 33C illustrate the structural formulas of R parts of the general forms illustrated in FIG. 32.

FIG. 33A illustrates the partial structure (trifluoromethyl group) of the fluorine additive for which all three H (hydrogen) atoms of a methyl group are substituted with the F atoms, as an example. FIG. 33B illustrates the partial structure (undecafluoropentoxyl group) of the fluorine additive for which 11 H atoms of a pentoxyl group are substituted with the F atoms, as an example. In the present embodiment, by adjusting the number of the F atoms in the functional group (partial structure), the fluorine content of the fluorine additive can be adjusted.

FIG. 33C illustrates the fluorine additive including the OH group as the reaction point. When the molecule of the fluorine additive includes the reaction point, a different molecule of the same fluorine additive can bond with the reaction point. In this case, by adjusting the number of times of repeating the application of the fluorine additive, the amount of the F atoms can be adjusted, and the amount of the F atoms to be diffused can be controlled as a result.

As above, the channel semiconductor layer 12 of the present embodiment is formed to include the semiconductor region 12a including the silicon (Si) and the semiconductor region 12b including the silicon (Si) and the carbon (C), similarly to the channel semiconductor layer 12 of the first embodiment or the like. Therefore, the present embodiment makes it possible to improve the performance of the channel semiconductor layer 12 and the other parts, similarly to the cases of the first to third embodiments.

In addition, the present embodiment makes it possible to easily achieve the uniform thickness of the semiconductor region 12b and the uniform distribution of the F atoms by forming the semiconductor region 12b using the fluorine additive such as the silylating agent.

### Fifth Embodiment

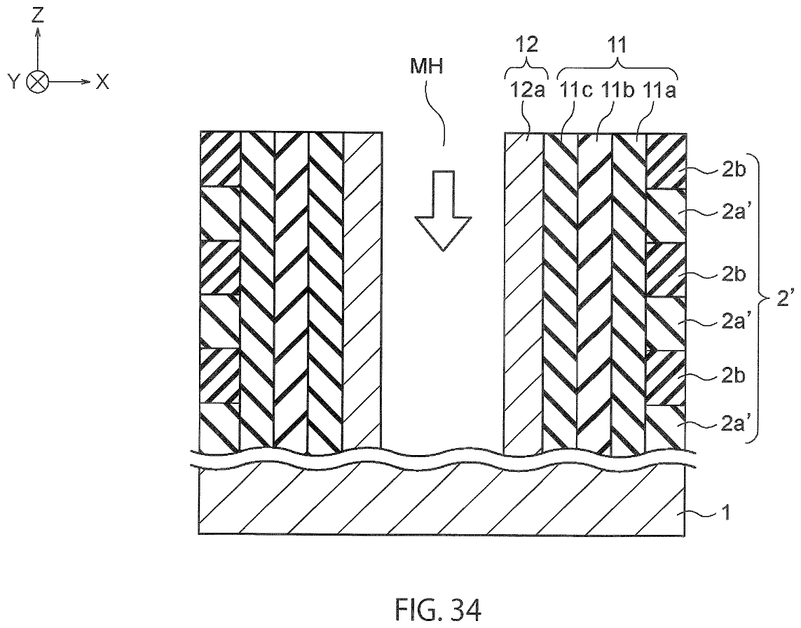

FIGS. 34 to 36 are sectional views illustrating a method of manufacturing a semiconductor device of the fifth embodiment.

First, after executing the processes illustrated in FIG. 2 to FIG. 4, the fluorine additive is supplied into each memory hole MH (FIG. 34). As a result, the fluorine additive is attached to the side face of the semiconductor region 12a in each memory hole MH. The fluorine additive of the present embodiment is the same as the fluorine additive of the fourth embodiment.

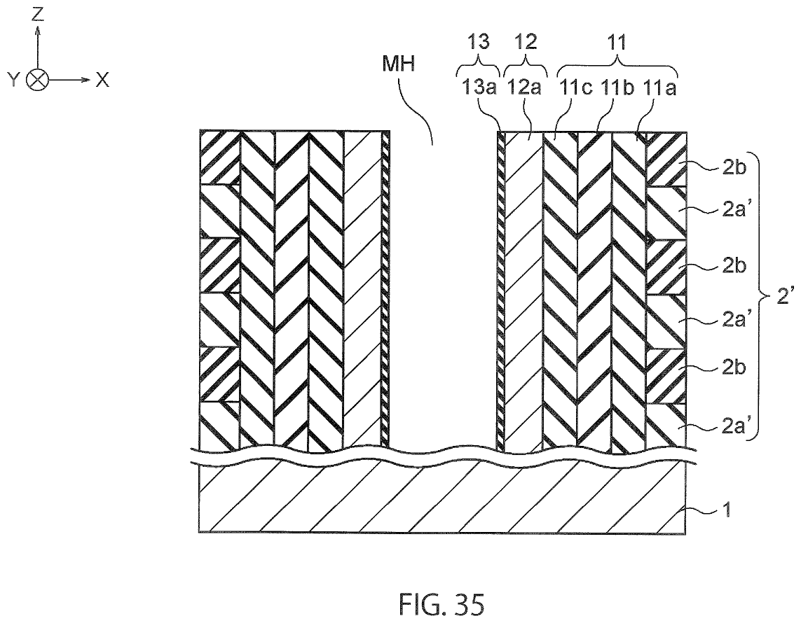

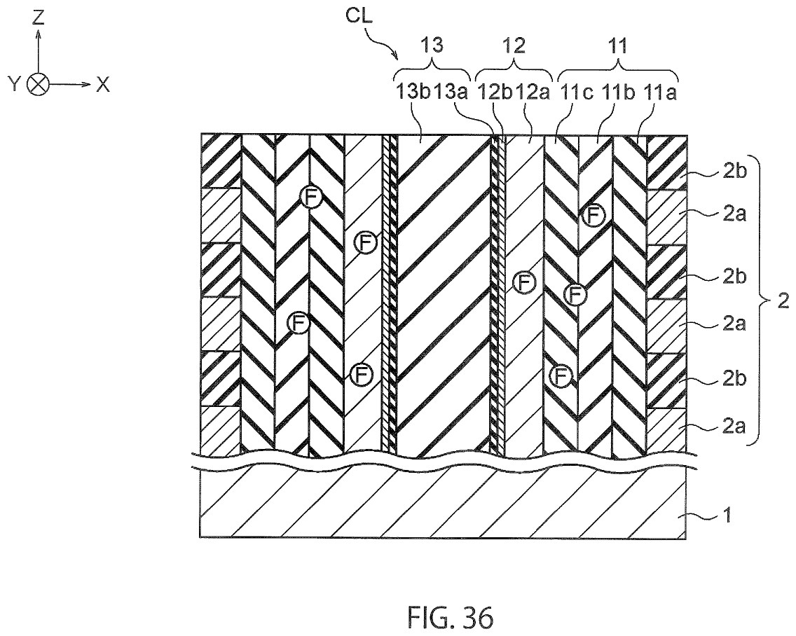

Next, an insulator 13a and an insulator 13b are formed in order on the side face of the semiconductor region 12a in each memory hole MH (FIG. 35 and FIG. 36), and the modification annealing of the insulator 13b and the additional annealing thereafter are performed (FIG. 36). As a result, the semiconductor region 12b is formed between the semiconductor region 12a and the insulator 13a, and the F atoms originating from the fluorine additive are diffused in the semiconductor region 12b, the semiconductor region 12a, the tunnel insulator 11c, the charge storage layer 11b and the block insulator 11a and in the interfaces between them. FIG. 36 schematically illustrates the F atoms diffused in this way. In the present embodiment, by the C atoms originating from the fluorine additive, the SiC film is formed as the semiconductor region 12b.

Before performing the modification annealing, the silylating agent is present in the interface between the semiconductor region 12a and the insulator 13a. The silylating agent is decomposed into the C atoms and the F atoms by the heat of the modification annealing and the additional annealing. As a result, the C atoms form the semiconductor region 12b as described above, and the F atoms are diffused as described above. This makes it possible to obtain the effects similar to the effects by the SiC film and the F atoms of the first to fourth embodiments.

In the present embodiment, the insulator 13a is the SiN film, the insulator 13b is the SiO₂ film, and the core insulator 13 is the stacked film including the insulator 13a and the insulator 13b, for example. The insulator 13a is an example of a third film. Generally, for the SiN film, a diffusion coefficient of the F atoms is low. Therefore, the present embodiment makes it possible to suppress the diffusion of the F atoms not to the side of the semiconductor region 12a but to the side of the insulator 13b by forming the insulator 13b on the side face of the semiconductor region 12a via the insulator 13a. The insulator 13a may be an insulator other than the SiN film, having the low diffusion coefficient of the F atoms.

Thereafter, the various interconnect layers, plug layers and inter layer dielectrics or the like are formed above the substrate 1. In this way, the semiconductor device of the present embodiment is manufactured.

The present embodiment makes it possible to easily achieve the uniform thickness of the semiconductor region 12b and the uniform distribution of the F atoms by forming the semiconductor region 12b using the fluorine additive such as the silylating agent.

Further, the present embodiment makes it possible to suppress the diffusion of the F atoms not to the side of the semiconductor region 12a but to the side of the insulator 13b by forming the insulator 13a on the side face of the semiconductor region 12a after attaching (supplying) the fluorine additive to the side face of the semiconductor region 12a.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

1. A semiconductor device comprising:
a substrate;
a plurality of electrode layers provided separately from each other in a first direction perpendicular to a surface of the substrate; and
a first insulator, a charge storage layer, a second insulator, a first semiconductor region including silicon, and a second semiconductor region including silicon and carbon, which are provided in order on side faces of the electrode layers,
wherein an interface between the first semiconductor region and the second insulator includes fluorine.

2. The device of claim 1, wherein a concentration of carbon atoms in the second semiconductor region is equal to or lower than 1.0×10²² cm⁻³.

3. The device of claim 1, wherein the first semiconductor region, the second insulator, the charge storage layer or the first insulator includes fluorine.

4. The device of claim 3, wherein a concentration of fluorine atoms in the first semiconductor region, the second insulator, the charge storage layer or the first insulator is equal to or lower than 1.0×10²² cm⁻³.

5. The device of claim 1, wherein a thickness of the first semiconductor region is equal to or smaller than 3 nm.

6. The device of claim 1, wherein a thickness of the second semiconductor region is smaller than a thickness of the first semiconductor region.

7. The device of claim 1 further comprising a semiconductor layer provided between the substrate and the plurality of electrode layers and in contact with the first semiconductor region.

8. The device of claim 7, wherein the first semiconductor region includes a third semiconductor region including p-type impurity atoms or n-type impurity atoms in a lower end portion of the first semiconductor region.

9. The device of claim 8, wherein a concentration of the p-type impurity atoms or the n-type impurity atoms in the third semiconductor region in contact with the semiconductor layer is higher than a concentration of the p-type impurity atoms or the n-type impurity atoms in the third semiconductor region in contact with the second insulator.

10. The device of claim 8, wherein a concentration of fluorine atoms in an interface between the third semiconductor region and the second insulator is substantially uniform over the interface.

11. The device of claim 1, wherein the charge storage layer is provided in an intersection portion of the first and second semiconductor regions extending in the first direction and the electrode layers extending in a second direction different from the first direction.

12. A method of manufacturing a semiconductor device, comprising:
forming a plurality of first films separated from each other in a first direction perpendicular to a surface of a substrate; and
forming a first insulator, a charge storage layer, a second insulator, a first semiconductor region including silicon, and a second semiconductor region including silicon and carbon in order on side faces of the first films,
wherein the first semiconductor region and the second insulator are formed to include fluorine in an interface between the first semiconductor region and the second insulator.

13. The method of claim 12, further comprising:
forming a second film including carbon and fluorine on a side face of the first semiconductor region before forming the second semiconductor region,
wherein the second film is heated such that the second semiconductor region is formed between the first semiconductor region and the second film, and that fluorine is supplied to the interface between the first semiconductor region and the second insulator.

14. The method of claim 13, wherein the second film is formed using a CₓH_{y}F_{z} gas where “C” denotes carbon, “H” denotes hydrogen, “F” denotes fluorine, “x” denotes an integer equal to or larger than 1, “y” denotes an integer equal to or larger than 0, and “z” denotes an integer equal to or larger than 1.

15. The method of claim 12 further comprising:
supplying a liquid or gaseous substance including carbon and fluorine to a side face of the first semiconductor region before forming the second semiconductor region,
wherein the substance is heated such that the second semiconductor region is formed on the side face of the first semiconductor region, and that fluorine is supplied to an interface between the first semiconductor region and the second insulator.

16. The method of claim 15, wherein the substance includes a silylating agent.

17. The method of claim 15, further comprising forming a third film including silicon and nitrogen on the side face of the first semiconductor region after supplying the substance and before forming the second semiconductor region.

18. The method of claim 12, wherein electrode layers are formed as the first films, or insulators are formed as the first films and the insulators are replaced with electrode layers.

19. The method of claim 12, wherein the first semiconductor region, the second insulator, the charge storage layer or the first insulator is formed to include fluorine.

20. The method of claim 19, wherein the first semiconductor region, the second insulator, the charge storage layer or the first insulator is formed to have a fluorine concentration equal to or lower than 1.0×10²² cm⁻³.
